(19) United States
(12) Patent Application Publication
(10) Pub. No.: US 2024/0332155 A1
(43) Pub. Date: Oct. 3, 2024

(54) SUBSTRATES WITH A GLASS CORE AND GLASS BUILDUP LAYERS

(71) Applicant: Intel Corporation, Santa Clara, CA (US)

(72) Inventors: Jianyong Mo, Chandler, AZ (US); Jason Michael Gamba, Gilbert, AZ (US); Liang Zhang, Chandler, AZ (US)

(73) Assignee: Intel Corporation, Santa Clara, CA (US)

(21) Appl. No.: 18/194,550

(22) Filed: Mar. 31, 2023

(51) Int. Cl. H01L 23/498; H01L 21/48; H01L 23/00; H01L 23/48; H01L 23/538; H01L 25/065

(52) U.S. Cl. CPC H01L 23/49838; H01L 21/486; H01L 23/481; H01L 23/5384; H01L 23/5389; H01L 24/24; H01L 24/82; H01L 25/0655; H01L 23/15; H01L 23/49894; H01L 24/32; H01L 24/73; H01L 24/92; H01L 2224/24101; H01L 2224/24137; H01L 2224/32225; H01L 2224/73267; H01L 2224/82106; H01L 2224/92244

(57) ABSTRACT

Substrates with a glass core and glass buildup layers, and methods of forming the same, are described herein. In one example, a substrate includes a glass core, glass layers above and below the glass core, conductive traces in the glass core and at least some of the glass layers, and conductive contacts on a surface of the substrate.

### BACKGROUND

The demand for the miniaturization of computing device form factors and increased levels of integration to achieve high performance in computing devices is helping drive the development of sophisticated packaging approaches in the semiconductor industry. Scaling down electrical input/output (I/O) interconnects has been one of the biggest drivers of improved performance. However, for microbump-based interconnects, scaling down the bump pitch beyond 10 microns (μm) has reached a wall of technical challenges. As a result, other interconnect technologies with more scalability have been gaining momentum, such as hybrid bonding, which is a combination of dielectric bonding and direct copper-to-copper bonding. Hybrid bonding is used for silicon-to-silicon bonding, such as bonding multiple silicon dies, wafers, etc. However, interconnects between silicon dies and package substrates are still primarily implemented using microbumps.

### BRIEF DESCRIPTION OF THE DRAWINGS

FIG. 1 illustrates a glass package substrate for hybrid-bonded silicon dies.

FIGS. 2A-J illustrate a process flow for forming a glass package substrate for hybrid-bonded silicon dies.

FIG. 3 illustrates an embedded-die package in a glass substrate.

FIGS. 4A-I illustrate a process flow for forming an embedded-die package in a glass substrate.

FIG. 5 illustrates an embedded-die package in a glass substrate using through-silicon vias.

FIGS. 6A-I illustrate a process flow for forming an embedded-die package in a glass substrate using through-silicon vias.

FIGS. 7A-C illustrate various embodiments of glass substrates and packages with microbumps.

FIG. 8 illustrates a flowchart for forming an integrated circuit (IC) package on a substrate with a glass core and glass buildup layers.

FIG. 9 is a top view of a wafer and dies that may be included in a microelectronic assembly.

FIG. 10 is a cross-sectional side view of an integrated circuit device that may be included in a microelectronic assembly.

FIG. 11 is a cross-sectional side view of an integrated circuit device assembly that may include a microelectronic assembly.

FIG. 12 is a block diagram of an example electrical device that may include a microelectronic assembly.

### DETAILED DESCRIPTION

Competition in high-performance computing has increased in intensity over the last decade. The demand for the miniaturization of computing device form factors and increased levels of integration to achieve high performance in computing devices is helping drive the development of sophisticated packaging approaches in the semiconductor industry.

Scaling down electrical input/output (I/O) interconnects has been one of the biggest drivers of improved performance. However, for microbump-based interconnects, scaling down the bump pitch beyond 10 microns (μm) has reached a wall of technical challenges. As a result, other interconnect technologies have been gaining momentum. For example, direct copper-to-copper bonding (e.g., without solder) is a promising alternative to microbumps to drive the bump pitch below 10 μm. Another promising alternative is hybrid bonding, which is a combination of dielectric bonding and copper-to-copper bonding.

Current hybrid bonding technology is limited to silicon-to-silicon bonding, such as wafer to wafer, die to wafer, die to die/die stack, etc. However, package substrates are typically made out of materials other than silicon. As a result, interconnects between silicon dies and (non-silicon) package substrates are still primarily implemented using microbumps.

Package substrates are typically made out of organic materials or a combination of glass and organic materials. For example, organic substrates typically include an organic core with multiple organic buildup layers, and glass substrates typically include a glass core with multiple organic buildup layers. For both types of substrates, the organic buildup layers are typically formed with an organic film such as Ajinomoto Build-up Film (ABF) and polyimide (PI). Organic materials have a high coefficient of thermal expansion (CTE), however, which causes them to expand significantly in high temperatures. As a result, these substrates are unsuitable for hybrid bonding, as the organic materials in these substrates will expand, which causes stress to the package and may lead to defects.

Accordingly, this disclosure presents embodiments of all-glass (or mostly-glass) substrates that are suitable for both microbump bonding and hybrid die-to-substrate bonding (e.g., copper-to-copper/dielectric bonding). Current glass-based substrates only use glass in the substrate core, while the buildup layers are formed using organic materials (e.g., ABF, PI), which makes them poor candidates for hybrid bonding. However, the glass substrates in this disclosure include a glass core and glass buildup layers, thus fully utilizing the electrical and mechanical benefits of glass.

These glass substrates can be formed by starting with a glass core and replacing the traditional organic build up layers with glass layers, such as by forming silicon oxidation layers on the glass core using chemical vapor deposition (CVD), physical vapor deposition (PVD), or other similar techniques.

Processes that are typically only used on the glass core-such as through-glass via (TGV) formation with laser-based etching techniques (e.g., laser-induced selected etching (LISE)) and conductive seeding and plating (e.g., titanium/copper seeding with copper plating)—can also be used on the glass buildup layers to form the electrical interconnects.

The back end of the substrate can have microbumps for traditional die attach with thermal compression bonding and mass reflow, or alternatively, it can have recessed Cu bumps within the glass (e.g., silicon oxidation) layers for direct hybrid bonding with silicon chips.

These glass substrates provide various advantages. For example, organic buildup layers are replaced with glass layers that can be closely matched to the glass core. This provides more flexibility in the substrate design, which was previously limited by manufacturing capabilities.

This all-glass substrate utilizes the mechanical and electrical benefits of glass more effectively compared to traditional glass-based substrates that only utilize glass in the core. For example, the resulting glass substrate has better electrical and mechanical properties, such as lower dielectric loss, higher bandwidth, lower CTE, lower warpage, and so forth.

Moreover, this all-glass design can be used for both microbump bonding and hybrid bonding. In particular, this design enables hybrid bonding between the die and the substrate for lower latency, higher bandwidth communication. For example, the mechanical properties of the glass layers can be fine-tuned to match that of silicon for hybrid bonding. Direct copper-to-copper bonding between a monolithic die, or die stack, to a substrate brings significant performance benefits. Further, this all-glass substrate can be manufactured and hybrid bonded with silicon chips at the panel or wafer level.

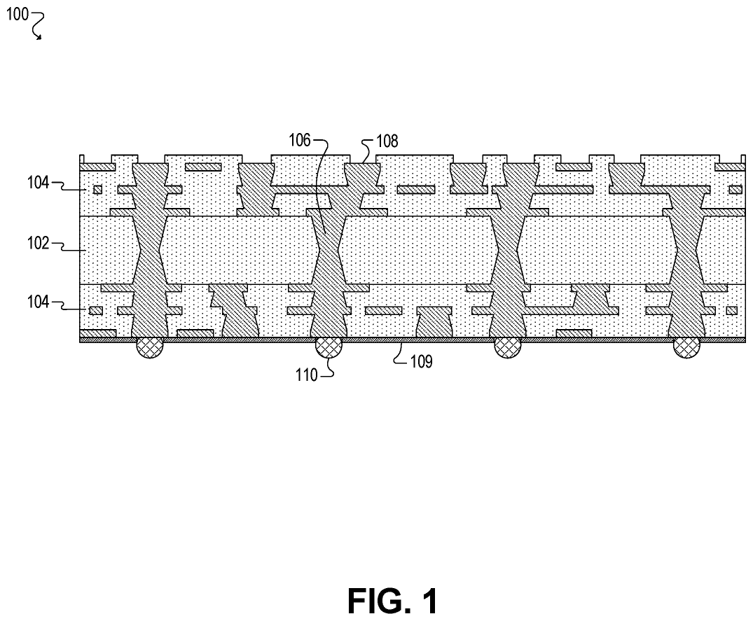

FIG. 1 illustrates a glass package substrate 100 for hybrid-bonded silicon dies. In some embodiments, for example, the glass substrate 100 may be used in an integrated circuit package where one or more integrated circuit dies are hybrid bonded to the glass substrate 100.

The glass substrate 100 includes a glass core 102 with glass buildup layers 104 above and below the core. In various embodiments, the glass core 102 may be a glass substrate made of any suitable glass (e.g., amorphous) materials, including, without limitation, oxides of silicon (SiOₓ) (e.g., silicon dioxide (SiO₂), also known as silica), fused silica, alkali glass, non-alkali glass, borosilicate glass, floated borosilicate glass (e.g., BOROFLOAT®), alkali borosilicate glass, quartz, and/or any other type of glass.

Thus, in various embodiments, the glass core 102 may be made of materials that include elements such as silicon, oxygen, boron, phosphorous, titanium, zinc, aluminum, magnesium, calcium, sodium, carbon, alkaline-earth metals, and/or any combination of those elements, including, without limitation, silicon dioxide (SiO₂) (e.g., with or without dopants such as boron, phosphorous, titanium, and/or zinc), calcium carbonate (CaCO₃), and sodium carbonate (Na₂CO₃).

The glass buildup layers 104 may be dielectric layers made of any suitable glass materials, including, without limitation, oxides of silicon (SiOₓ) (e.g., silicon dioxide (SiO₂) aka silica, fused silica), spin-on glass (e.g., glass materials such as silica (SiO₂) with dopants such as boron, phosphorous, titanium, and/or zinc), and so forth. Thus, in some embodiments, the glass buildup layers 104 may be made of materials that include elements such as silicon, oxygen, boron, phosphorous, titanium, zinc, aluminum, magnesium, calcium, sodium, carbon, alkaline-earth metals, and/or any combination of those elements, including, without limitation, silicon dioxide (SiO₂) (e.g., with or without dopants such as boron, phosphorous, titanium, and/or zinc), calcium carbonate (CaCO₃), and sodium carbonate (Na₂CO₃). Further, in some embodiments, the properties of the glass layers 104 (e.g., the CTE) may be tuned to match those of silicon for hybrid bonding with silicon dies.

The package substrate 100 also includes conductive traces 106 patterned in the glass core 102 and the glass buildup layers 104, including vias in the glass core 102 and glass layers 104 and horizontal traces in the glass layers 104. In some embodiments, the conductive traces may be made of metal 106 (e.g., copper and/or titanium).

The conductive traces 106 electrically couple the recessed pads 108 at the top of the package substrate 100 with the bumps 110 at the bottom of the substrate. The recessed pads 108 and bumps 110 are conductive contacts used to electrically couple other components to the package substrate 100. The recessed pads 108 may be copper pads that are recessed slightly below the dielectric glass layers 104, and the bumps 110 may be solder balls, bumps, or microbumps. The package substrate 100 also includes a layer of solder resist 109 at the bottom of the substrate where the bumps 110 are located.

In some embodiments, for example, one or more integrated circuit dies (not shown) may be coupled to the top side of the package substrate 100 and hybrid bonded to the recessed pads 108 (e.g., via a combination of dielectric and copper-to-copper bonding). Further, the package substrate 100 may be coupled to a circuit board (e.g., a motherboard, main board, etc.) or another integrated circuit package (not shown) via the bumps 110 at the bottom of the package substrate 100.

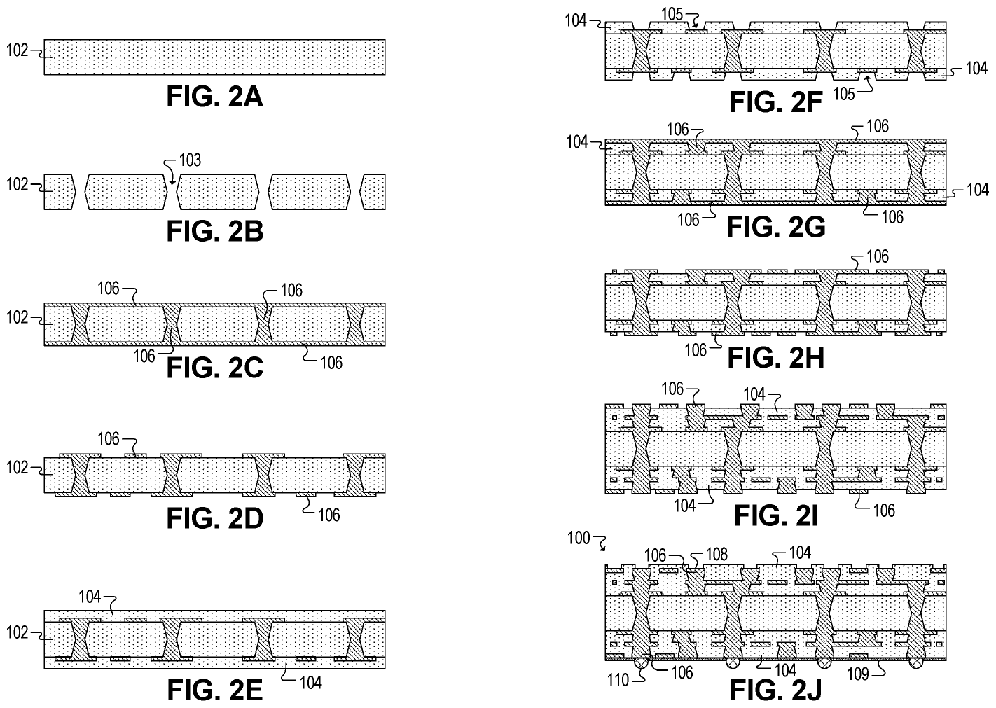

FIGS. 2A-J illustrate a process flow for forming the glass package substrate 100 of FIG. 1. In particular, the illustrated process flow can be used for panel-level or wafer-level manufacturing of glass substrates for hybrid-bonded silicon dies (e.g., substrate-to-die hybrid bonding). However, this process flow is only one example methodology for manufacturing such substrates.

In FIG. 2A, an amorphous glass panel (or wafer) with an appropriate thickness is used as the substrate core 102. In some embodiments, the glass panel may have a thickness ranging from 100 microns (μm) to 1000 μm, or 1 millimeter (mm). A variety of glass compositions can be used depending on the process requirements, including, without limitation, alkali glass, non-alkali glass, borosilicate glass, floated borosilicate glass (e.g., BOROFLOAT®), alkali borosilicate glass, and/or quartz, among other examples.

In FIG. 2B, through holes 103 are formed in the glass core 102. In some embodiments, the through holes 103 are formed using laser-based techniques, such as laser-induced selective etching (LISE). LISE is a two-step process where the glass is modified locally using an ultrafast laser pulse, and the modified portions are etched away using wet chemical etching techniques (e.g., an etch bath with hydrogen fluoride (HF), potassium hydroxide (KOH), or sodium hydroxide (NaOH)). The laser-impacted area has a much faster etching rate compared to the non-impacted area, which enables the formation of high-aspect-ratio through holes 103.

In FIG. 2C, metal seeding and plating is performed to form electrically conductive paths 106 through the core 102 and above/below the core 102. For example, titanium and copper may be deposited on the surfaces of the core 102 and through holes 103 to form seed layers, and copper may be deposited on the seed layers to form through-glass vias (TGVs) 106 in the core 102 (e.g., by filling the through holes 103) and conductive layers 106 above and below the core 102. Polishing techniques may be used to planarize the surface of the conductive layers on the core 102 (e.g., grinding, chemical mechanical planarization (CMP)).

In FIG. 2D, the conductive layers on the top and bottom of the core 102 are patterned into conductive traces 106 by etching away the unwanted metal. In some embodiments, traditional lithographic processes may be used to etch away the unwanted metal, such as dry film resist (DFR) lamination, photoexposure, photoresist development, and copper etching.

In FIG. 2E, glass buildup layers 104 are formed above and below the core 102. For example, instead of laminating organic buildup layers on the core (e.g., using ABF film), glass layers 104 with an appropriate thickness (e.g., 10-50 μm) are formed above and below the core 102 by depositing a suitable material for forming glass.

In some embodiments, the glass layers 104 may be silicon oxidation layers formed by depositing an oxide of silicon (SiOₓ), such as silicon dioxide (SiO₂) (also known as silica), onto the core 102 using chemical vapor deposition (CVD) or physical vapor deposition (PVD), which solidifies into glass. Different doping materials and concentrations can be carefully chosen to modify the silicon oxidation formers and modifiers to obtain desired electrical and mechanical properties in the resulting glass layers 104.

Polishing techniques may then be used to planarize the surfaces of the glass layers 104 (e.g., grinding, chemical mechanical planarization (CMP)).

In FIG. 2F, via holes 105 are formed in the glass layers 104. For example, instead of forming traditional via holes in organic buildup layers (e.g., ABF) using laser drilling, the via holes 105 are formed in glass buildup layers 104. As a result, the via holes 105 in the glass layers 104 can be formed using the same LISE process as the via holes 103 in the glass core 102 from FIG. 2B, which means the same tooling set can be utilized.

In FIG. 2G, a second set of vias/conductive layers 106 are formed on the glass layers 104 above and below the core 102 using similar metallization and surface planarization techniques as the first set of vias/conductive layers in FIG. 2C.

Similarly, in FIG. 2H, the conductive layers 106 at the top and bottom are patterned into conductive traces 106 using the same etching techniques as in FIG. 2D.

In FIG. 2I, the steps from FIGS. 2E-H are repeated to form another set of glass buildup layers 104 and conductive buildup layers 106 on the top and bottom surfaces. These steps can be repeated until the appropriate number of glass/conductive buildup layers for the particular substrate have been formed.

In FIG. 2J, another glass layer 104 is formed on the bottom surface and planarized (e.g., flush with the layer of traces 106), a solder resist layer 109 is formed on the glass layer 104, and bumps or microbumps 110 are formed on the traces 106 to create the second level interconnect.

Another glass layer 104 is also formed on the top surface-slightly elevated relative to the layer of traces 106—and then planarized (e.g., using CMP) to form an extremely flat dielectric glass surface 104, with copper pads 108 recessed slightly below the surface 104 (e.g., by 5-20 nm). The recessed copper pads 108 form the first level interconnect for hybrid bonding with one or more silicon dies (not shown). In some embodiments, hybrid bonding may be performed at the panel level between a panel of glass substrates 100 and the silicon die(s). As noted above, the properties of the dielectric glass layers 104, such as the CTE, may be fine-tuned to match those of silicon by adding silicon formers, replacers, and/or modifiers. As a result, the glass substrate 100 can be hybrid bonded to the silicon dies without causing stress or damage to the substrate 100.

In the illustrated example, the process flow is described at a high level. Certain steps are omitted for simplicity and/or may be different from those described herein without departing from the scope of the described embodiments. For simplicity, only a limited number of glass/conductive buildup layers 104, 106 are shown in substrate 100. In actual embodiments, the number of buildup layers may be up to 20 layers or more. Further, the number of buildup layers above and below the core does not necessarily have to be the same.

Compared to substrates with a glass core and organic buildup layers, the all-glass (or mostly glass) substrates described herein provide numerous benefits. For example, the described embodiments support hybrid bonding between a glass substrate and silicon die, which enables higher interconnect density and shorter interconnect distance between the substrate and die compared to microbump interconnects. In addition, since the materials used for the glass buildup layers can be very similar to those used for the glass core, these glass substrates also have various mechanical/structural benefits, such as lower warpage, which increases yield. The described embodiments also require fewer tools to manufacture, which results in significant cost savings.

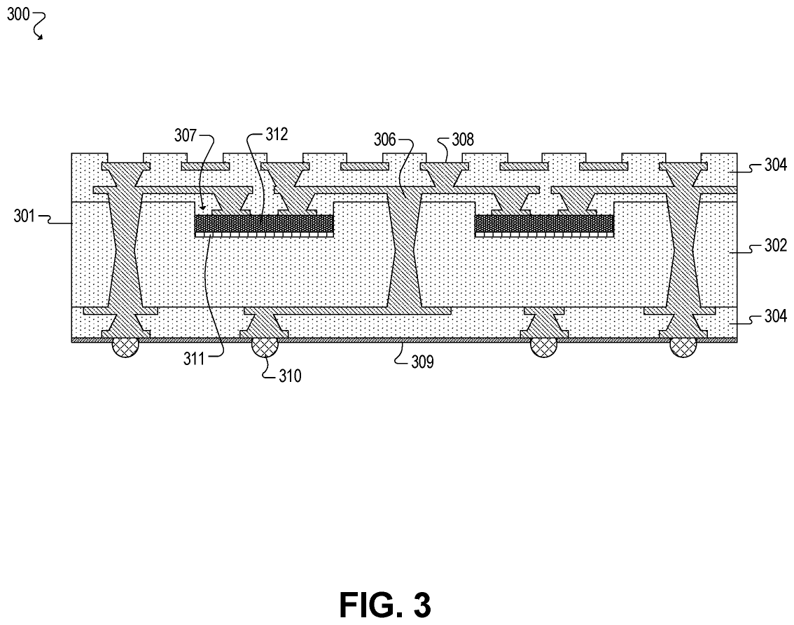

FIG. 3 illustrates an embedded-die package 300 in a glass substrate 301. The embedded-die package 300 is an integrated circuit package with silicon dies 312 embedded in the glass substrate 301.

In the illustrated embodiment, the glass substrate 301 includes a glass core 302, which may be a glass substrate made of any suitable glass (e.g., amorphous) materials, including, without limitation, oxides of silicon (SiOₓ) (e.g., silicon dioxide (SiO₂) aka silica), fused silica, alkali glass, non-alkali glass, borosilicate glass, floated borosilicate glass (e.g., BOROFLOAT®), alkali borosilicate glass, quartz, and/or any other type of glass. Thus, in various embodiments, the glass core 302 may be made of materials that include elements such as silicon, oxygen, boron, phosphorous, titanium, zinc, aluminum, magnesium, calcium, sodium, carbon, alkaline-earth metals, and/or any combination of those elements, including, without limitation, silicon dioxide (SiO₂) (e.g., with or without dopants such as boron, phosphorous, titanium, and/or zinc), calcium carbonate (CaCO₃), and sodium carbonate (Na₂CO₃).

Moreover, the glass core 302 includes multiple cavities 307 with embedded silicon dies 312, which are attached to the floor of the respective cavities 307 using die attach film (DAF) 311.

The glass substrate 301 also includes glass buildup layers 304 above and below the glass core 302. The glass buildup layers 304 may be dielectric layers made of any suitable glass materials, including, without limitation, oxides of silicon (SiOₓ) (e.g., silicon dioxide (SiO₂) aka silica, fused silica), spin-on glass (e.g., glass materials such as silica (SiO₂) with dopants such as boron, phosphorous, titanium, and/or zinc), and so forth. Thus, in some embodiments, the glass buildup layers 304 may be made of materials that include elements such as silicon, oxygen, boron, phosphorous, titanium, zinc, aluminum, magnesium, calcium, sodium, carbon, alkaline-earth metals, and/or any combination of those elements, including, without limitation, silicon dioxide (SiO₂) (e.g., with or without dopants such as boron, phosphorous, titanium, and/or zinc), calcium carbonate (CaCO₃), and sodium carbonate (Na₂CO₃). Further, in some embodiments, the properties of the glass layers 304, such as the CTE, may be tuned to match those of silicon (e.g., for hybrid bonding with silicon chips).

The substrate 301 also includes conductive traces 306 patterned in the glass core 302 and the glass buildup layers 304, including vias in the glass core 302 and glass layers 304 and horizontal traces in the glass layers 304. In some embodiments, the conductive traces 306 may be made of metal (e.g., copper and/or titanium).

The conductive traces 306 electrically couple the embedded dies 312, the recessed pads 308 at the top of the substrate 301, and the bumps 310 at the bottom of the substrate 301. The recessed pads 308 and bumps 310 are conductive contacts used to electrically couple other components to the substrate 301. The recessed pads 308 may be copper pads that are recessed slightly below the dielectric glass layers 304, and the bumps 310 may be solder balls, bumps, or microbumps. The substrate 301 also includes a layer of solder resist 309 at the bottom of the substrate where the bumps 310 are located.

In some embodiments, for example, one or more additional silicon dies (not shown) may be hybrid bonded to the recessed pads 308 (e.g., via a combination of dielectric and copper-to-copper bonding) on the top side of the substrate 301. Further, the substrate 301 may be coupled to a circuit board (e.g., a motherboard, main board, etc.) or another integrated circuit package (not shown) via the bumps 310 at the bottom of the substrate 301.

For simplicity, embedded dies 312 are only shown on the top side of the core 302. In other embodiments, however, passive components (e.g., traces 306) and active silicon dies 312 can be embedded on both sides of the core 302, or in the glass buildup layers 304 (e.g., using embedded multi-die interconnects/bridges), or across both the core 302 and the glass buildup layers 304.

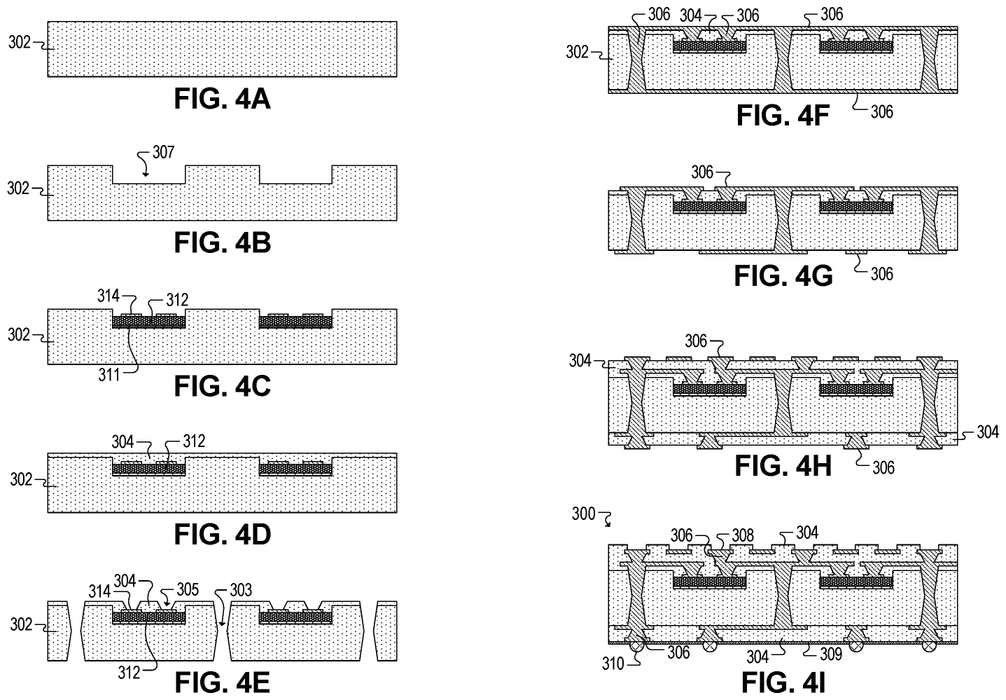

FIGS. 4A-I illustrate a process flow for forming the embedded-die package 300 of FIG. 3. In particular, the illustrated process flow is used to embed active dies and passive components (e.g., traces/bridges/interconnects) in a glass substrate. However, this process flow is only one example methodology for manufacturing such packages.

In FIG. 4A, a glass panel (or wafer) with an appropriate thickness is used as the substrate core 302 (e.g., similar to FIG. 2A).

In FIG. 4B, cavities 307 for silicon dies are formed in the core 302 (e.g., using LISE processes).

In FIG. 4C, silicon dies 312 are mounted to the bottom of the cavities 307 using die attach film (DAF) 311 with precise alignment and tip-tilt control. The dies 312 include pads 314 on the top surface for interconnections to other components.

In FIG. 4D, silicon oxidation deposition is used to form a glass layer 304 to fill the gaps above the dies 312, and the glass layer 304 is planarized (e.g., using grinding and/or CMP).

In FIG. 4E, through holes 303 are formed in the glass core 302, and via holes 305 are formed in the glass layer 304 to the pads 314 on the silicon die 312 (e.g., using LISE processes).

In FIG. 4F, metal seeding and plating is performed to form conductive paths 306 through the core 302, to the silicon dies 312, and above and below the core 302 (e.g., on the glass layer 304). For example, through-glass vias (TGVs) 306 are formed in the core 302 by filling the through holes 303 with metal, vias 306 are formed in in the glass layer 304 by filling the via holes 305 with metal, and conductive layers 306 are formed above/below the core 302 by depositing metal below the core 302 and above the core 302 on the glass layer 304.

The remaining steps in FIGS. 4G, 4H, and 4I are similar to those in FIGS. 2H, 2I, and 2J, respectively.

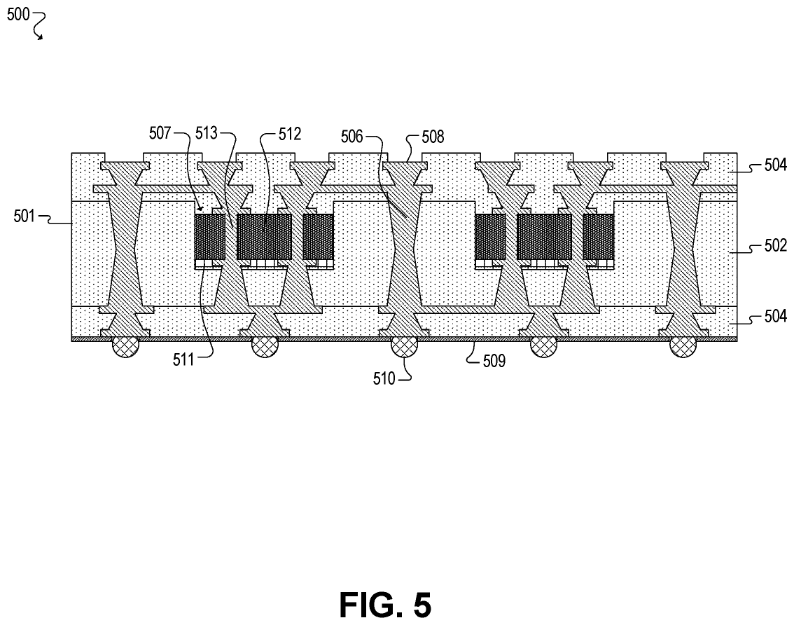

FIG. 5 illustrates an embedded-die package 500 in a glass substrate using through-silicon vias. For example, the embedded-die package 500 is an integrated circuit package in a glass substrate 501 with embedded silicon dies 512 that have through-silicon vias (TSVs) 513.

In the illustrated embodiment, the glass substrate 501 includes a glass core 502, which may be a glass substrate made of any suitable glass (e.g., amorphous) materials, including, without limitation, oxides of silicon (SiOₓ) (e.g., silicon dioxide (SiO₂) aka silica), fused silica, alkali glass, non-alkali glass, borosilicate glass, floated borosilicate glass (e.g., BOROFLOAT®), alkali borosilicate glass, quartz, and/or any other type of glass. Thus, in various embodiments, the glass core 502 may be made of materials that include elements such as silicon, oxygen, boron, phosphorous, titanium, zinc, aluminum, magnesium, calcium, sodium, carbon, alkaline-earth metals, and/or any combination of those elements, including, without limitation, silicon dioxide (SiO₂) (e.g., with or without dopants such as boron, phosphorous, titanium, and/or zinc), calcium carbonate (CaCO₃), and sodium carbonate (Na₂CO₃).

Moreover, the glass core 502 includes multiple cavities 507 with embedded silicon dies 512, which are attached to the floor of the respective cavities 507 using die attach film (DAF) 511. The embedded silicon dies 512 include through-silicon vias (TSV) 513 to electrically couple the dies 512 to conductive traces 506 above and below the dies 512 in the substrate 501.

The glass substrate 501 also includes glass buildup layers 504 above and below the glass core 502. The glass buildup layers 504 may be dielectric layers made of any suitable glass materials, including, without limitation, oxides of silicon (SiOₓ) (e.g., silicon dioxide (SiO₂) aka silica, fused silica), spin-on glass (e.g., glass materials such as silica (SiO₂) with dopants such as boron, phosphorous, titanium, and/or zinc), and so forth. Thus, in some embodiments, the glass buildup layers 504 may be made of materials that include elements such as silicon, oxygen, boron, phosphorous, titanium, zinc, aluminum, magnesium, calcium, sodium, carbon, alkaline-earth metals, and/or any combination of those elements, including, without limitation, silicon dioxide (SiO₂) (e.g., with or without dopants such as boron, phosphorous, titanium, and/or zinc), calcium carbonate (CaCO₃), and sodium carbonate (Na₂CO₃). Further, in some embodiments, the properties of the glass layers 504, such as the CTE, may be tuned to match those of silicon (e.g., for hybrid bonding with silicon chips).

The substrate 501 also includes conductive traces 506 patterned in the glass core 502 and the glass buildup layers 504, including vias in the glass core 502 and glass layers 504 and horizontal traces in the glass layers 504. In some embodiments, the conductive traces 506 may be made of metal (e.g., copper and/or titanium).

The conductive traces 506 electrically couple the embedded dies 512, the recessed pads 508 at the top of the substrate 501, and the bumps 510 at the bottom of the substrate 501. The recessed pads 508 and bumps 510 are conductive contacts used to electrically couple other components to the substrate 501. The recessed pads 508 may be copper pads that are recessed slightly below the dielectric glass layers 504, and the bumps 510 may be solder balls, bumps, or microbumps. The substrate 501 also includes a layer of solder resist 509 at the bottom of the substrate where the bumps 510 are located.

In some embodiments, for example, one or more additional silicon dies (not shown) may be hybrid bonded to the recessed pads 508 (e.g., via a combination of dielectric and copper-to-copper bonding) on the top side of the substrate 501. Further, the substrate 501 may be coupled to a circuit board (e.g., a motherboard, main board, etc.) or another integrated circuit package (not shown) via the bumps 510 at the bottom of the substrate 501.

For simplicity, embedded dies 512 are only shown on the top side of the core 502. In other embodiments, however, passive components (e.g., traces 506) and active silicon dies 512 can be embedded on both sides of the core 502, or in the glass buildup layers 504 (e.g., using embedded multi-die interconnects/bridges), or across both the core 502 and the glass buildup layers 504.

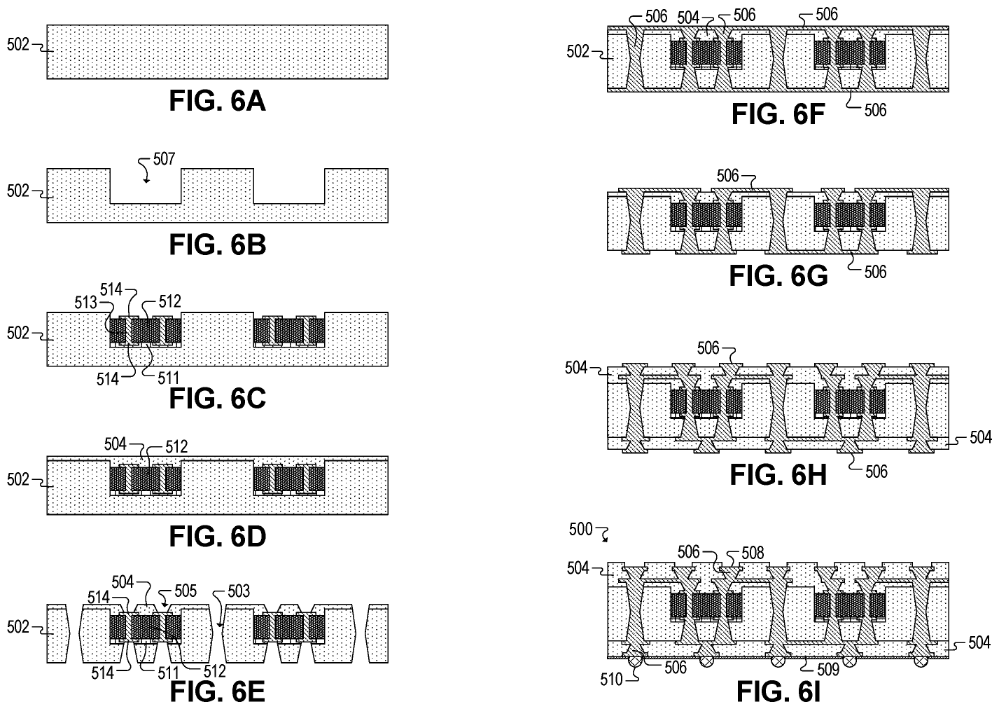

FIGS. 6A-I illustrate a process flow for forming the embedded-die package 500 of FIG. 5. This process flow is only one example methodology for manufacturing such packages.

The process flow shown in FIGS. 6A-I for embedded-die package 500 is similar to the process flow shown in FIGS. 4A-I for embedded-die package 300, except as noted below.

In FIG. 6C, the dies 512 mounted in the cavities 507 include through-silicon vias (TSV) 513 connected to pads 514 on the top and bottom of the dies 512.

In FIG. 6E, via holes 505 are formed in the glass core 502 to the die pads 514 on bottom of the embedded dies 512 (e.g., in addition to the via holes 505 in the glass layer 504 to the die pads 514 on top of the dies 512, and the through holes 503 in the glass core 502). Moreover, the die attach film 511 on the bottom die pads 514 is removed (e.g., with lasers) to enable an electrical connection between the bottom die pads 514 and the subsequently formed vias.

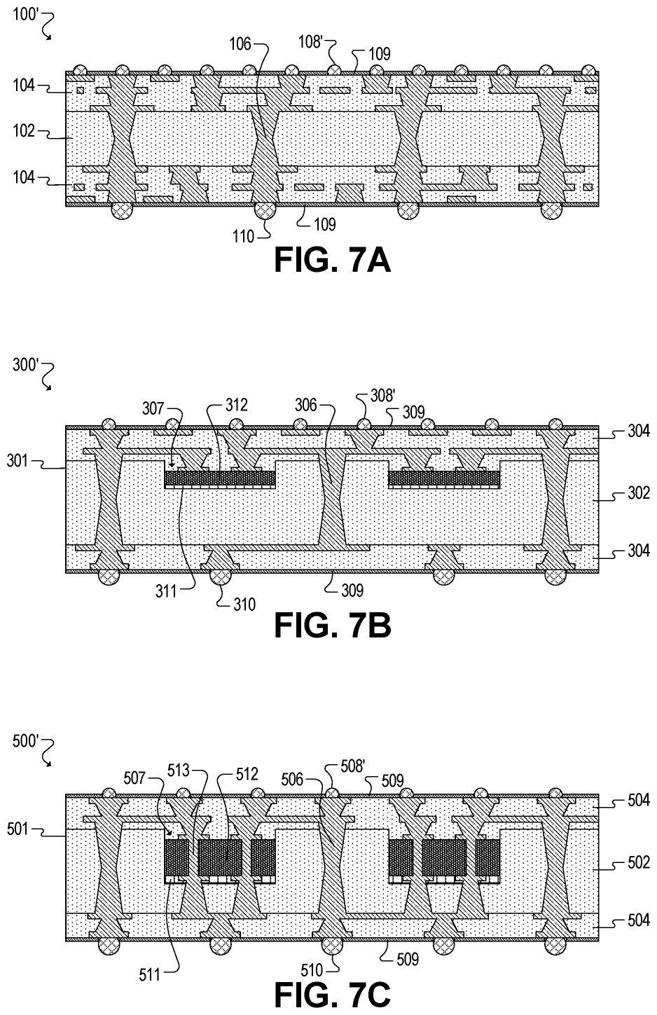

FIGS. 7A-C illustrate various embodiments of glass substrates and packages with microbumps. In particular, FIGS. 7A, 7B, and 7C depict the embodiments of FIGS. 1, 3, 5, respectively, where the first level interconnect on the top surface is formed by microbumps rather than recessed pads for hybrid bonding. In this manner, one or more silicon dies (or other integrated circuit packages/components) may be attached to the top surface via the microbumps.

For example, FIG. 7A illustrates a glass package substrate 100′ with microbumps 108′ on the top surface, FIG. 7B illustrates a glass embedded-die package 300′ with microbumps 308′ on the top surface, and FIG. 7C illustrates a glass embedded-die package 500′ with through-silicon vias 513 in the embedded dies 512 and microbumps 508′ on the top surface.

The embodiments in FIGS. 7A, 7B, and 7C can be manufactured using similar process flows as described in FIGS. 2A-J, 4A-I, and 6A-I, respectively. In the last stage of the process, however, solder resist and bumps are added on both sides of the glass substrates rather than only on bottom. Traditional bumping technologies can be used to form the bumps for the first level interconnect (on top) and the second level interconnect (on bottom). In this manner, traditional bump/microbump bonding is used on all-glass substrates-rather than organic substrates or glass-core-only substrates—to take full advantage of the electrical and mechanical benefits of glass.

In the embodiments shown and described throughout this disclosure (e.g., substrates/packages 100, 100′, 300, 300′, 500, 500′), other types of conductive contacts may be used instead of, or in addition to, those shown, including, without limitation, metal pads (e.g., recessed or non-recessed copper pads), metal bumps/microbumps (e.g., C2/C4 copper bumps), solder balls/bumps, and solder paste, among other examples.

Further, in various embodiments, the glass substrates described herein may be “all-glass” substrates or “mostly-glass” substrates, meaning the core is made of glass and all or some of the dielectric buildup layers are made of glass. In some embodiments, for example, the glass core may be made of solid glass (and patterned with various integrated circuitry features) rather than glass cloth or fabric. Further, in some embodiments, all dielectric buildup layers may be glass layers, while in other embodiments, there may be a combination of glass buildup layers and non-glass buildup layers, where the non-glass buildup layers are made of other dielectric materials, such as organic materials (e.g., ABF, solder resist). Further, the glass core and/or the glass/dielectric buildup layers may be patterned with various features, including, without limitation, vias/traces, conductive contacts (e.g., pads, bumps), recesses, cavities, embedded silicon dies, and so forth.

Moreover, the described glass substrates can be used as substrates in any type of electronic device, including integrated circuit packages, circuit boards (e.g., printed circuit boards), and so forth.

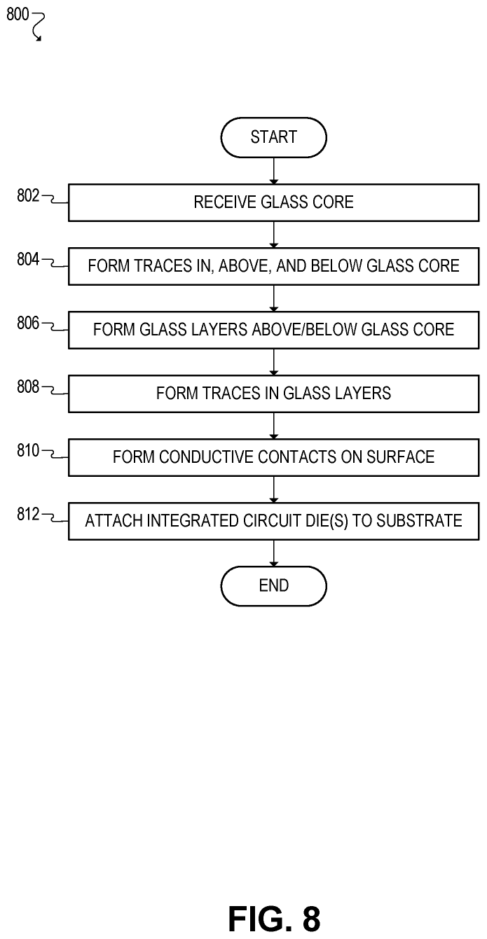

FIG. 8 illustrates a flowchart 800 for forming an integrated circuit (IC) package on a substrate with a glass core and glass buildup layers. It will be appreciated in light of this disclosure that flowchart 800 is only one example methodology for arriving at an IC package on a substrate with a glass core and glass buildup layers.

The steps of flowchart 800 may be performed using any suitable semiconductor fabrication techniques. For example, patterning and removal—such as interconnect patterning, forming via openings, and shaping—may be performed using any suitable techniques, such as lithography-based patterning/masking and/or etching. Moreover, film deposition—such as depositing layers, filling portions of layers (e.g., removed portions), and filling via openings—may be performed using any suitable deposition techniques, including, for example, electroless deposition, chemical vapor deposition (CVD), metal organic chemical vapor deposition (MOCVD), molecular beam epitaxy (MBE), atomic layer deposition (ALD), and/or physical vapor deposition (PVD).

The flowchart begins at block 802 by receiving a glass panel (or wafer) to use as the core of a substrate for the IC package. The glass core may be formed of any type of glass. In some embodiments, the glass core may be made of materials that include elements such as silicon, oxygen, boron, phosphorous, titanium, zinc, aluminum, magnesium, calcium, sodium, carbon, alkaline-earth metals, and/or any combination of those elements, including, without limitation, silicon dioxide (SiO₂) (e.g., with or without dopants such as boron, phosphorous, titanium, and/or zinc), calcium carbonate (CaCO₃), and sodium carbonate (Na₂CO₃).

The flowchart then proceeds to block 804 to form traces in the glass core and above/below the glass core. For example, through holes may be formed in the glass core and filled with a conductive material (e.g., metal) to form through-glass vias through the core. Further, conductive layers may be formed above and below the core and etched into an appropriate pattern of conductive traces. In some embodiments, the conductive material used to form the traces may include a metal, such as copper, titanium, tin, silver, gold, nickel, aluminum, tungsten, and/or alloys thereof.

The flowchart then proceeds to block 806 to form glass layers above and below the glass core. Further, in some embodiments, the properties of the glass layers, such as the CTE, may be tuned to match that of the glass core and/or silicon (e.g., for hybrid bonding with silicon dies).

In some embodiments, for example, the glass layers may be dielectric layers made of any suitable glass materials, including, without limitation, oxides of silicon (SiOₓ) (e.g., silicon dioxide (SiO₂) aka silica, fused silica), spin-on glass (e.g., glass materials such as silica (SiO₂) with dopants such as boron, phosphorous, titanium, and/or zinc), and so forth. Thus, in some embodiments, the glass layers may be made of materials that include elements such as silicon, oxygen, boron, phosphorous, titanium, zinc, aluminum, magnesium, calcium, sodium, carbon, alkaline-earth metals, and/or any combination of those elements, including, without limitation, silicon dioxide (SiO₂) (e.g., with or without dopants such as boron, phosphorous, titanium, and/or zinc), calcium carbonate (CaCO₃), and sodium carbonate (Na₂CO₃).

The flowchart then proceeds to block 808 to form traces in the glass layers above and below the core, including vias and horizontal traces.

Blocks 806 and 808 may be repeated as many times as needed to form the appropriate number of glass buildup layers patterned with conductive traces above and below the core.

The flowchart then proceeds to block 810 to form conductive contacts on one or more surfaces of the substrate (e.g., on the top and/or bottom glass layers and coupled to the traces), such as metal pads (e.g., recessed or non-recessed copper pads), metal bumps/microbumps (e.g., C2/C4 copper bumps), solder balls/bumps, and solder paste, among other examples.

In some embodiments, for example, recessed pads (e.g., for hybrid bonding) or microbumps may be formed on the top surface of the glass substrate for the first level interconnect to one or more integrated circuit dies. Further, bumps may be formed on the bottom surface of the glass substrate for the second level interconnect to a circuit board (e.g., a motherboard, main board, etc.) or another integrated circuit package.

In this manner, the completed package substrate includes a glass core, glass buildup layers above and below the glass core, conductive traces patterned in the glass core and glass buildup layers, and conductive contacts on the surface(s) of the substrate for the first and/or second level interconnects.

The flowchart then proceeds to block 812 to attach one or more integrated circuit (IC) dies to the substrate. In some embodiments, for example, one or more dies may be attached to the top of the glass substrate, such as by hybrid bonding the dies to recessed copper pads on the substrate surface, or attaching the dies to microbumps on the substrate surface, among other examples. Alternatively, in some embodiments, one or more cavities may be formed in the glass core and/or the glass layers during earlier stages of processing, and one or more silicon dies may be embedded in the cavities and interconnected with the conductive traces patterned in the glass buildup layers.

The integrated circuit die(s) may include any suitable type of circuitry, including, but not limited to, processing circuitry, communication circuitry, and/or memory/storage circuitry. In some embodiments, for example, the integrated circuit die(s) may include a central processing unit (CPU), graphics processing unit (GPU), vision processing unit (VPU), microprocessor, microcontroller, field-programmable gate array (FPGA), application-specific integrated circuit (ASIC), input/output (I/O) controller, network interface controller (NIC), memory, and/or solid-state storage, among other examples.

The completed IC package may subsequently be attached to or included as part of a circuit board, another integrated circuit substrate or package, or an electronic device (e.g., electronic device 1200).

In some embodiments, for example, the IC package may be included in an electronic device such as a cell phone, a wearable device, a computer, a server, a camera, a video playback device, a video game console, a display device, a vehicle control unit, or an appliance, among other examples.

At this point, the flowchart may be complete. In some embodiments, however, the flowchart may restart and/or certain blocks may be repeated. For example, in some embodiments, the flowchart may restart at block 802 to form another integrated circuit package with the same or similar design.

### Example Integrated Circuit Embodiments

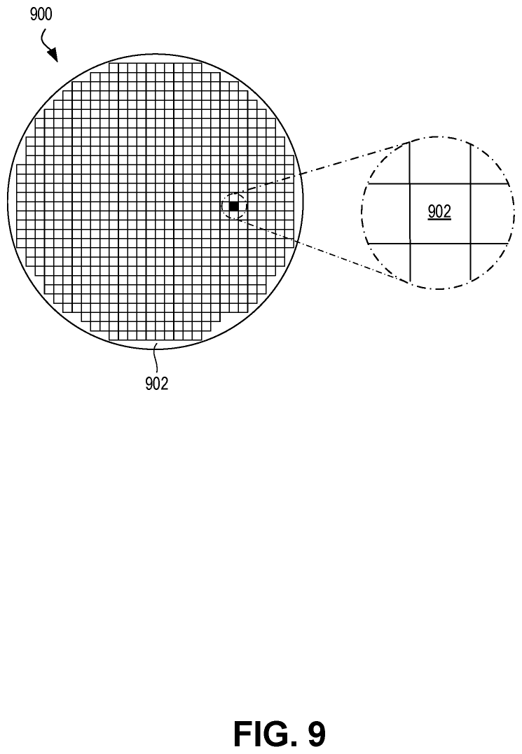

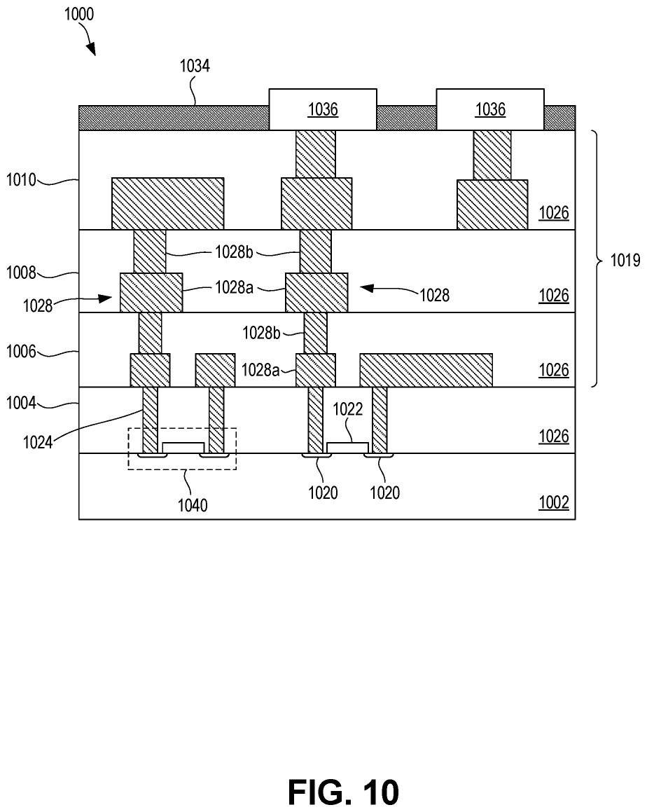

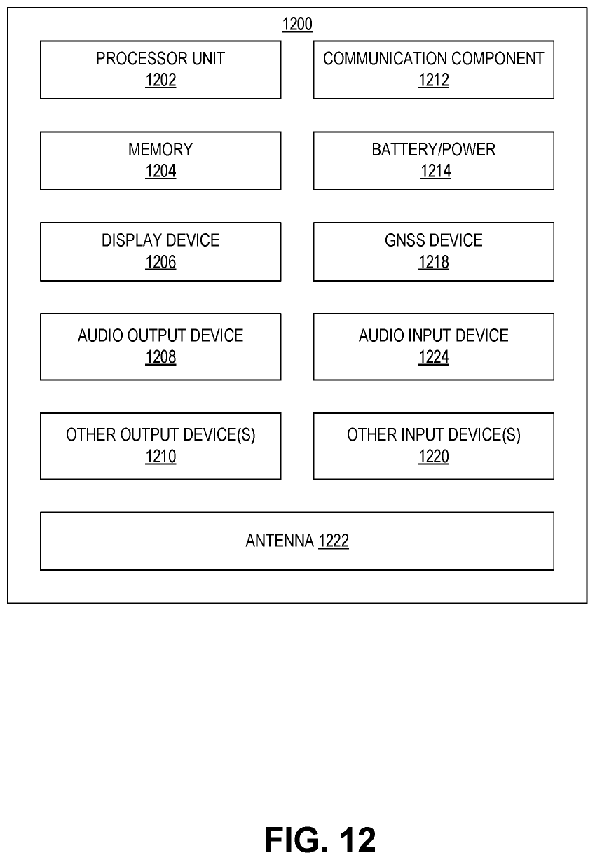

FIG. 9 is a top view of a wafer 900 and dies 902 that may be included in any of the embodiments disclosed herein. The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may be any of the dies disclosed herein. The die 902 may include one or more transistors (e.g., some of the transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1202 of FIG. 12) or other logic that is configured to store information in the memory devices or execute instructions stored in the memory array. Various ones of the microelectronic assemblies disclosed herein may be manufactured using a die-to-wafer assembly technique in which some dies are attached to a wafer 900 that include others of the dies, and the wafer 900 is subsequently singulated.

FIG. 10 is a cross-sectional side view of an integrated circuit device 1000 that may be included in any of the embodiments disclosed herein (e.g., in any of the dies). One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 10, a transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page from the perspective of FIG. 10. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board). The integrated circuit device 1000 may include additional or alternate structures to route the electrical signals from the interconnect layers 1006-1010; for example, the conductive contacts 1036 may include other analogous features (e.g., posts) that route the electrical signals to external components. The conductive contacts 1036 may serve as any of the conductive contacts described throughout this disclosure.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036. These additional conductive contacts may serve as any of the conductive contacts described throughout this disclosure.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. These additional conductive contacts may serve as any of the conductive contacts described throughout this disclosure. In some embodiments, TSVs extending through the substrate can be used for routing power and ground signals from conductive contacts on the opposite side of the integrated circuit device 1000 from the conductive contacts 1036 to the transistors 1040 and any other components integrated into the die 1000, and the metallization stack 1019 can be used to route I/O signals from the conductive contacts 1036 to transistors 1040 and any other components integrated into the die 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

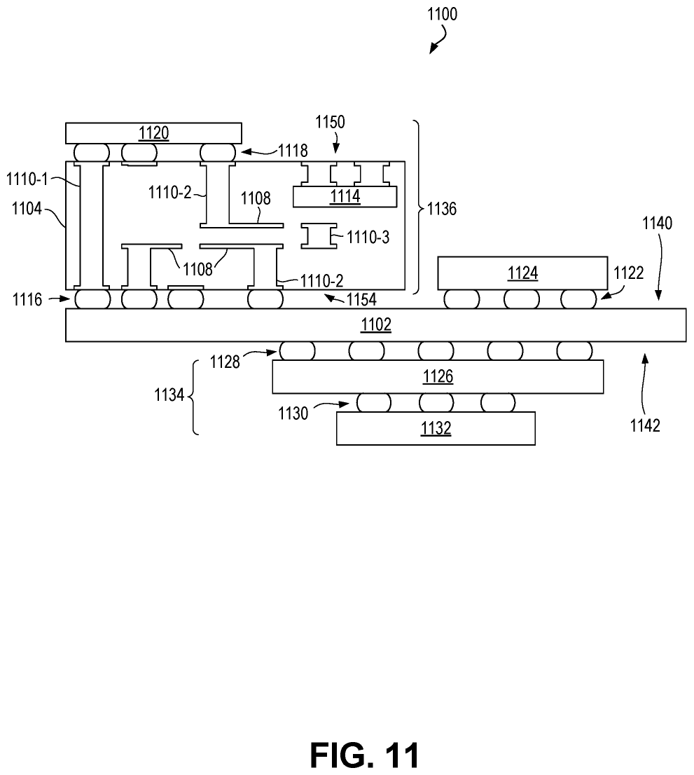

FIG. 11 is a cross-sectional side view of an integrated circuit device assembly 1100 that may include any of the embodiments disclosed herein. For example, any suitable component of integrated circuit device assembly 1100 may include one or more of the glass substrates/packages 100, 300, 500 disclosed herein. In some embodiments, the integrated circuit device assembly 1100 may be a microelectronic assembly. The integrated circuit device assembly 1100 includes a number of components disposed on a circuit board 1102 (which may be a motherboard, system board, mainboard, etc.). The integrated circuit device assembly 1100 includes components disposed on a first face 1140 of the circuit board 1102 and an opposing second face 1142 of the circuit board 1102; generally, components may be disposed on one or both faces 1140 and 1142. Any of the integrated circuit components discussed below with reference to the integrated circuit device assembly 1100 may take the form of any suitable ones of the embodiments of the microelectronic assemblies 100 disclosed herein.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The integrated circuit device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1116 may serve as the coupling components illustrated or described for any of the substrate assembly or substrate assembly components described herein, as appropriate.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpacked integrated circuit product that includes one or more integrated circuit dies (e.g., the die 902 of FIG. 9, the integrated circuit device 1000 of FIG. 10) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1120, a single monolithic integrated circuit die comprises solder bumps attached to contacts on the die. The solder bumps allow the die to be directly attached to the interposer 1104. The integrated circuit component 1120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1120 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets.” In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through silicon vias (TSV) extending through the silicon interposer can connect connections on a first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art. In embodiments where the interposer is a non-printed circuit board

The integrated circuit device assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit device assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include one or more of the embodiments disclosed herein. For example, any suitable ones of the components of the electrical device 1200 may include one or more of the glass substrates/packages 100, 100′, 300, 300′, 500, 500′, integrated circuit device assemblies 1100, integrated circuit components 1120, integrated circuit devices 1000, or integrated circuit dies 902 disclosed herein. A number of components are illustrated in FIG. 12 as included in the electrical device 1200, but any one or more of these components may be omitted or duplicated, as suitable for the application. In some embodiments, some or all of the components included in the electrical device 1200 may be attached to one or more motherboards mainboards, or system boards. In some embodiments, one or more of these components are fabricated onto a single system-on-a-chip (SoC) die.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1200 can comprise one or more processor units 1202 that are heterogeneous or asymmetric to another processor unit 1202 in the electrical device 1200. There can be a variety of differences between the processing units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include other output device(s) 1210 (or corresponding interface circuitry, as discussed above). Examples of the other output device(s) 1210 may include an audio codec, a video codec, a printer, a wired or wireless transmitter for providing information to other devices, or an additional storage device.

The electrical device 1200 may include other input device(s) 1220 (or corresponding interface circuitry, as discussed above). Examples of the other input device(s) 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

### EXAMPLE EMBODIMENTS

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a substrate, comprising: a glass core; a plurality of glass layers on the glass core, wherein some of the glass layers are above the glass core and some of the glass layers are below the glass core; a plurality of conductive traces, wherein the conductive traces are in the glass core and at least some of the glass layers; and a plurality of conductive contacts on one or more surfaces of the substrate.

Example 2 includes the substrate of Example 1, wherein the conductive traces comprise: a plurality of vias, wherein the vias are in the glass core and at least some of the glass layers; and a plurality of horizontal traces, wherein the horizontal traces are in at least some of the glass layers.

Example 3 includes the substrate of any of Examples 1-2, wherein at least some of the conductive contacts are to be electrically coupled to a circuit board or an integrated circuit package.

Example 4 includes the substrate of any of Examples 1-3, wherein at least some of the conductive contacts are to be electrically coupled to an integrated circuit die.

Example 5 includes the substrate of Example 4, wherein the conductive contacts to be electrically coupled to the integrated circuit die comprise: a plurality of microbumps; or a plurality of pads.

Example 6 includes the substrate of Example 5, wherein the pads are recessed relative to the glass layers.

Example 7 includes the substrate of any of Examples 1-6, wherein the glass core has a thickness ranging from approximately 100-1000 microns.

Example 8 includes the substrate of any of Examples 1-7, wherein at least some of the glass layers have a thickness ranging from approximately 10-50 microns.

Example 9 includes the substrate of any of Examples 1-8, wherein at least some of the glass layers comprise silicon and oxygen.

Example 10 includes the substrate of any of Examples 1-9, wherein the conductive traces comprise at least one of copper or titanium.

Example 11 includes an integrated circuit package, comprising: an integrated circuit die; and a package substrate electrically coupled to the integrated circuit die, wherein the package substrate comprises: a glass core; a plurality of glass layers on the glass core, wherein some of the glass layers are above the glass core and some of the glass layers are below the glass core; a plurality of conductive traces, wherein the conductive traces are in the glass core and at least some of the glass layers; and a plurality of conductive contacts on one or more surfaces of the package substrate.

Example 12 includes the integrated circuit package of Example 11, wherein at least some of the conductive contacts are to be electrically coupled to a circuit board or another integrated circuit package.

Example 13 includes the integrated circuit package of any of Examples 11-12, wherein at least some of the conductive contacts are electrically coupled to the integrated circuit die.

Example 14 includes the integrated circuit package of any of Examples 11-12, wherein the integrated circuit die is embedded in a cavity of the package substrate.

Example 15 includes the integrated circuit package of any of Examples 11-14, wherein the integrated circuit die comprises processing circuitry, communication circuitry, or memory circuitry.

Example 16 includes an electronic device, comprising: a circuit board; and an integrated circuit package electrically coupled to the circuit board, wherein the integrated circuit package comprises: one or more integrated circuit dies; and a package substrate electrically coupled to the one or more integrated circuit dies, wherein the package substrate comprises: a glass core; a plurality of glass layers on the glass core, wherein some of the glass layers are above the glass core and some of the glass layers are below the glass core; a plurality of conductive traces, wherein the conductive traces are in the glass core and at least some of the glass layers; and a plurality of conductive contacts on one or more surfaces of the package substrate.

Example 17 includes the electronic device of Example 16, wherein the electronic device is a cell phone, a wearable device, a computer, a server, a camera, a video playback device, a video game console, a display device, a vehicle control unit, or an appliance.

Example 18 includes a method, comprising: receiving a glass core; forming a plurality of glass layers on the glass core, wherein some of the glass layers are formed above the glass core and some of the glass layers are formed below the glass core; forming a plurality of conductive traces in the glass core and at least some of the glass layers; and forming a plurality of conductive contacts on one or more surfaces of the glass layers.

Example 19 includes the method of Example 18, further comprising: attaching an integrated circuit die to at least some of the conductive contacts.

Example 20 includes the method of Example 18, further comprising: forming a cavity in the glass core and/or at least some of the glass layers; and embedding an integrated circuit die in the cavity.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for case of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for case of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “between”, “adjacent”, “to”, and “on” as used herein may refer to a relative position of one layer or component with respect to other layers or components. For example, one layer “over” or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core allows for higher-density package architectures, as the through-vias have relatively large dimensions and pitch compared to high-density interconnects.

The term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

The term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and/or metallization structures. The substrate may mechanically support and electrically couple one or more IC dies on a single platform, with encapsulation of the one or more IC dies by a moldable dielectric material. The substrate may include solder bumps (or other conductive contacts) as bonding interconnects on one or both sides. One side of the substrate, generally referred to as the “die side”, may include solder bumps for chip or die bonding. The opposite side of the substrate, generally referred to as the “land side”, may include solder bumps for bonding the package to a printed circuit board.

The term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

The terms “coupled” or “connected” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

1. A substrate, comprising:
a glass core;
a plurality of glass layers on the glass core, wherein some of the glass layers are above the glass core and some of the glass layers are below the glass core;
a plurality of conductive traces, wherein the conductive traces are in the glass core and at least some of the glass layers; and
a plurality of conductive contacts on one or more surfaces of the substrate.

2. The substrate of claim 1, wherein the conductive traces comprise:
a plurality of vias, wherein the vias are in the glass core and at least some of the glass layers; and
a plurality of horizontal traces, wherein the horizontal traces are in at least some of the glass layers.

3. The substrate of claim 1, wherein at least some of the conductive contacts are to be electrically coupled to a circuit board or an integrated circuit package.

4. The substrate of claim 1, wherein at least some of the conductive contacts are to be electrically coupled to an integrated circuit die.

5. The substrate of claim 4, wherein the conductive contacts to be electrically coupled to the integrated circuit die comprise:
a plurality of microbumps; or
a plurality of pads.

6. The substrate of claim 5, wherein the pads are recessed relative to the glass layers.

7. The substrate of claim 1, wherein the glass core has a thickness ranging from approximately 100-1000 microns.

8. The substrate of claim 1, wherein at least some of the glass layers have a thickness ranging from approximately 10-50 microns.

9. The substrate of claim 1, wherein at least some of the glass layers comprise silicon and oxygen.

10. The substrate of claim 1, wherein the conductive traces comprise at least one of copper or titanium.

11. An integrated circuit package, comprising:
an integrated circuit die; and
a package substrate electrically coupled to the integrated circuit die, wherein the package substrate comprises:
a glass core;
a plurality of glass layers on the glass core, wherein some of the glass layers are above the glass core and some of the glass layers are below the glass core;
a plurality of conductive traces, wherein the conductive traces are in the glass core and at least some of the glass layers; and
a plurality of conductive contacts on one or more surfaces of the package substrate.

12. The integrated circuit package of claim 11, wherein at least some of the conductive contacts are to be electrically coupled to a circuit board or another integrated circuit package.

13. The integrated circuit package of claim 11, wherein at least some of the conductive contacts are electrically coupled to the integrated circuit die.

14. The integrated circuit package of claim 11, wherein the integrated circuit die is embedded in a cavity of the package substrate.

15. The integrated circuit package of claim 11, wherein the integrated circuit die comprises processing circuitry, communication circuitry, or memory circuitry.

16. An electronic device, comprising:
a circuit board; and
an integrated circuit package electrically coupled to the circuit board, wherein the integrated circuit package comprises:
one or more integrated circuit dies; and
a package substrate electrically coupled to the one or more integrated circuit dies, wherein the package substrate comprises:
a glass core;
a plurality of glass layers on the glass core, wherein some of the glass layers are above the glass core and some of the glass layers are below the glass core;
a plurality of conductive traces, wherein the conductive traces are in the glass core and at least some of the glass layers; and
a plurality of conductive contacts on one or more surfaces of the package substrate.

17. The electronic device of claim 16, wherein the electronic device is a cell phone, a wearable device, a computer, a server, a camera, a video playback device, a video game console, a display device, a vehicle control unit, or an appliance.

18. A method, comprising:
receiving a glass core;
forming a plurality of glass layers on the glass core, wherein some of the glass layers are formed above the glass core and some of the glass layers are formed below the glass core;
forming a plurality of conductive traces in the glass core and at least some of the glass layers; and
forming a plurality of conductive contacts on one or more surfaces of the glass layers.

19. The method of claim 18, further comprising:
attaching an integrated circuit die to at least some of the conductive contacts.

20. The method of claim 18, further comprising:
forming a cavity in the glass core and/or at least some of the glass layers; and
embedding an integrated circuit die in the cavity.
